(19) United States
(12) Patent Application Publication
(10) Pub. No.: US 2021/0233841 A1
(43) Pub. Date: Jul. 29, 2021

(54) SEMICONDUCTOR DEVICE

(71) Applicant: RENESAS ELECTRONICS CORPORATION, Tokyo (JP)

(72) Inventors: Shunji KUBO, Tokyo (JP); Kazuki NIINO, Tokyo (JP); Hajime HAYASHIMOTO, Tokyo (JP)

(21) Appl. No.: 16/752,925

(22) Filed: Jan. 27, 2020

(51) Int. Cl. H01L 23/522; H01L 23/528

(52) U.S. Cl. CPC H01L 23/5226; H01L 24/05; H01L 23/5283; H01L 23/5286

(57) ABSTRACT

A semiconductor device includes a semiconductor substrate, a semiconductor layer, an insulating film, a conductive film, a first electrode pad, a second electrode pad, and a third electrode pad. The semiconductor layer includes a first semiconductor region having a first conductivity type and a second semiconductor region having a second conductivity type opposite to the first conductivity type. The insulating film is formed on the semiconductor layer. The conductive film is formed on the second semiconductor region through the insulating film interposed therebetween. The first electrode pad is configured to be electrically connected with the first semiconductor region and is configured to be electrically connected with the power supply circuit. The second electrode pad is configured to be electrically connected with the second semiconductor region and is configured to allow a signal to be provided toward an external circuit through the second electrode pad.

### BACKGROUND

The present disclosure relates to a semiconductor device, for example a semiconductor device including a filter circuit.

There is disclosed technique listed below.
[Patent Document 1] Japanese Unexamined Patent Application Publication No. 2008-053257

A semiconductor device including filter circuit is known (see, e.g., Patent Document 1). The semiconductor device described in Patent Document 1 includes a high-pass filter circuit constituted by a capacitive element and a resistive element. In Patent Document 1, a high-pass filter circuit including a resistive element formed of polycrystal silicon is described as the resistive element.

### SUMMARY

However, the resistive element formed of the polycrystal silicon generally occupy some area in the semiconductor device. Therefore, there is a room for improvement in the conventional semiconductor device from the viewpoint of miniaturization of the semiconductor device. The problem of the embodiments is to miniaturize the semiconductor device. Other problems and novel features will become apparent from the description of the specification and drawings.

A semiconductor device according to embodiments includes: a semiconductor substrate; a first semiconductor region having a first conductivity type; a second semiconductor region having a second conductivity type opposite to the first conductivity type; and a semiconductor layer formed on the semiconductor substrate; an insulating film formed on the semiconductor layer; a conductive film formed on the second semiconductor region through the insulating film; a first electrode pad electrically connected with the first semiconductor region; a second electrode pad electrically connected with the second semiconductor region; and a third electrode pad electrically connected with the conductive film. The first electrode pad is configured to be electrically connected with a power supply circuit. The second electrode pad is configured to allow a signal to be output toward an external circuit through the second electrode pad.

According to embodiments, the semiconductor device can be miniaturized.

### BRIEF DESCRIPTION OF THE DRAWINGS

FIG. 1 is a circuit diagram showing an exemplary circuit configuration of a semiconductor device according to a first embodiment.

FIG. 2 is a waveform diagram showing an example of an input signal and an output signal in the low-pass filter circuit.

FIG. 3 is a plan view showing an exemplary configuration of a main portion of the semiconductor device according to the first embodiment.

FIG. 4 is a cross-sectional view showing an exemplary configuration of the main portion of the semiconductor device according to the first embodiment.

FIG. 5 is a cross-sectional view showing exemplary step included in a method of manufacturing the semiconductor device according to the first embodiment.

FIG. 6 is a cross-sectional view showing an exemplary step included in the method of manufacturing the semiconductor device according to the first embodiment.

FIG. 7 is a cross-sectional view showing an exemplary step included in the method of manufacturing the semiconductor device according to the first embodiment.

FIG. 8 is a cross-sectional view showing an exemplary step included in the method of manufacturing the semiconductor device according to the first embodiment.

FIG. 9 is a plan view showing an exemplary configuration of a main portion of a semiconductor device according to a first modification.

FIG. 10 is a plan view showing an exemplary configuration of a main portion of a semiconductor device according to a second modification.

FIG. 11 is a plan view showing an exemplary configuration of a main portion of a semiconductor device according to a third modification.

FIG. 12 is a circuit diagram showing an exemplary circuit configuration of a semiconductor device according to a second embodiment.

FIG. 13 is a cross-sectional view showing an exemplary configuration of a main portion of the semiconductor device according to the second embodiment.

FIG. 14 is a cross-sectional view showing an exemplary step included in a method of manufacturing the semiconductor device according to the second embodiment.

FIG. 15 is a cross-sectional view showing an exemplary step included in the method of manufacturing the semiconductor device according to the second embodiment.

FIG. 16 is a cross-sectional view showing an exemplary step included in the method of manufacturing the semiconductor device according to the second embodiment.

FIG. 17 is a cross-sectional view showing an exemplary step included in the method of manufacturing the semiconductor device according to the second embodiment.

FIG. 18 is a circuit diagram showing an exemplary circuit configuration of a comparative semiconductor device.

FIG. 19 is a circuit diagram showing an exemplary circuit configuration of the semiconductor device according to the second embodiment.

FIG. 20 is a circuit diagram showing an exemplary circuit configuration of the comparative semiconductor device.

### DETAILED DESCRIPTION

Hereinafter, semiconductor device according to embodiments will be described in detail by referring to the drawings. In the specification and drawings, the same or corresponding elements are denoted by the same reference numerals or hatching, and a repetitive description thereof is omitted. In the drawings, for convenience of description, a configuration may be omitted or simplified. A cross-sectional view may be shown as an end view. At least a part of each embodiment and each modification may be arbitrarily combined with each other.

### First Embodiment

A semiconductor device according to a first embodiment includes a low-pass filter circuit.

(Circuit Configuration of Semiconductor Device)

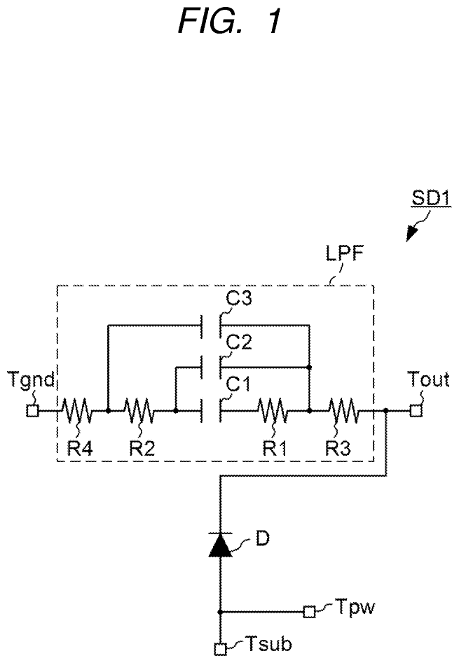

FIG. 1 is a circuit diagram showing an exemplary circuit configuration of a semiconductor device SD1 according to a first embodiment.

As shown in FIG. 1, the semiconductor device SD1 includes a diode element D and a low-pass filter circuit LPF. The low-pass filter circuit LPF includes a first resistive element R1, a second resistive element R2, a third resistive element R3, a fourth resistive element R4, a first capacitive element C1, a second capacitive element C2, and a third capacitive element C3. Further, the semiconductor device SD1 includes a substrate terminal Tsub, a power supply terminal Tpw, an output terminal Tout, and a grounding terminal Tgnd.

One end of the diode element D is coupled with the power supply terminal Tpw and the substrate terminal Tsub. Aother end of the diode element D is coupled with the output terminal Tout and the low-pass filter circuit LPF. The diode element D is a pn junction diode element. The diode element D passes only a forward current supplied from the power supply terminal Tpw.

In present embodiment, the filter characteristic of the low-pass filter circuit LPF is mainly determined by the first capacitive element C1. The first resistive element R1, the second resistive element R2, the third resistive element R3, the fourth resistive element R4, the second capacitive element C2, and the third capacitive element C3 can be used to adjust the filter characteristic of the low-pass filter circuit LPF.

The first resistive element R1, the second resistive element R2, the first capacitive element C1, the third resistive element R3, and the fourth resistive element R4 are coupled in series between the diode element D and the grounding terminal Tgnd. In the present embodiment, the fourth resistive element R4, the second resistive element R2, the first capacitive element C1, the first resistive element R1, and the third resistive element R3 are coupled in this order from the diode element D.

One end of the second capacitive element C2 is coupled with a node between the first resistive element R1 and the third resistive element R3. Another end of the second capacitive element C2 is coupled with a node between the second resistive element R2 and the first capacitive element C1.

One end of the third capacitive element C3 is coupled with a node between the first resistive element R1 and the third resistive element R3. Another end of the third capacitive element C3 is coupled with a node between the second resistive element R2 and the fourth resistive element R4.

The substrate terminal Tsub is configured to allow a predetermined fixed voltage to be supplied. The substrate terminal Tsub may be configured to allow, for example, a grounding potential to be supplied.

The power supply terminal Tpw is configured to allow a predetermined power supply potential to be supplied. The power supply terminal Tpw is coupled with, for example, a power supply (not shown).

The output terminal Tout is configured to allow signal output to output toward another circuit. The output terminal Tout is coupled with, for example, an electronic circuit (not shown). The electronic circuit is not particularly limited, and is, for example, a band gap reference (BGR) circuit.

The grounding terminal Tgnd is configured to allow a grounding potential to be supplied.

The substrate terminal Tsub, the power supply terminal Tpw, the output terminal Tout, and the grounding terminal Tgnd may be respectively a internal terminal (electrode pad) formed in the semiconductor device SD1, or an external terminal formed in circuit outside the semiconductor device SD1.

(Operation of Semiconductor Device SD1)

Subsequently, the operation of the semiconductor device SD1 according to the first embodiment is explained.

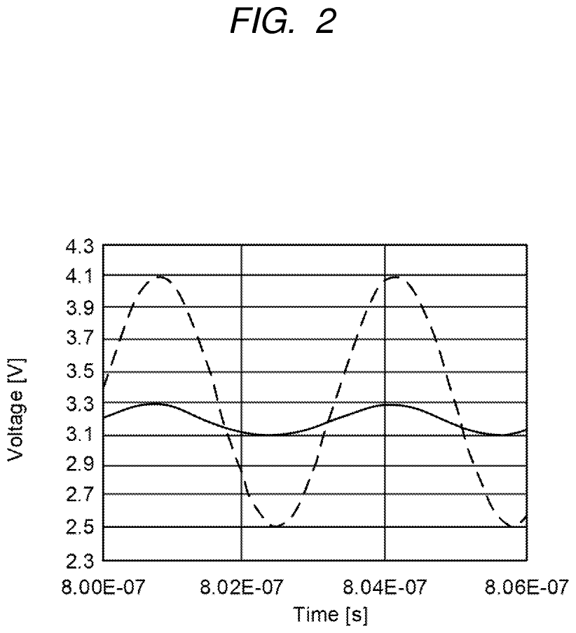

FIG. 2 is a waveform diagram showing an example of an input signal and an output signal in the low-pass filter circuit LPF. In FIG. 2, the horizontal axis represents time [s], and the vertical axis represents voltage value [V]. In FIG. 2, a broken line shows an example of an input signal input toward the power supply terminal Tpw. A solid line shows an example of output signal output from the output terminal Tout.

As shown in FIG. 2, the diode element D transmits a signal from the power supply terminal Tpw in the forward direction. The signal passing through the diode element D reaches the low-pass filter circuit LPF. Subsequently, the low-pass filter circuit LPF attenuates a high-frequency component of a predetermined frequency or more of the components contained in the input signal. As a result, the low-pass filter circuit LPF passes a low-frequency component smaller than the predetermined frequency.

(Configuration of Semiconductor Device)

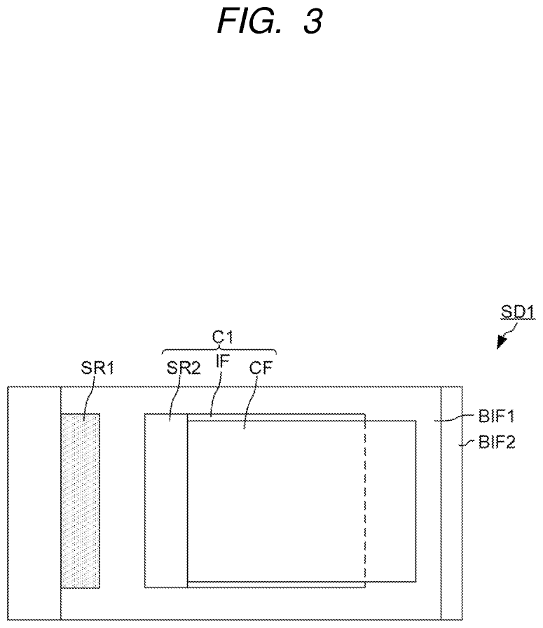

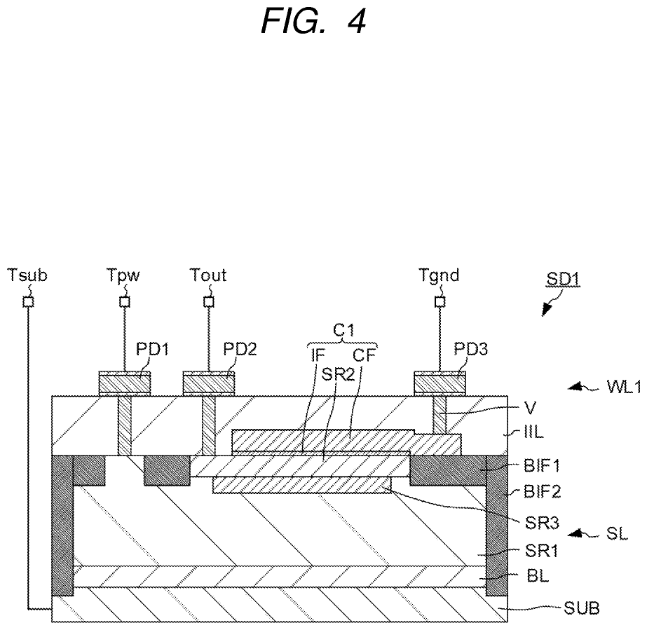

FIGS. 3 and 4 show exemplary configurations of the semiconductor device SD1 for realizing the above-described circuit configuration. FIG. 3 is a plan view showing an exemplary configuration of a main portion of the semiconductor device SD1. FIG. 4 is a cross-sectional view showing an exemplary configuration of the main portion of the semiconductor device SD1. In FIG. 3, a part of the configuration is omitted from the viewpoint of ease of viewing. In FIG. 3, the first semiconductor area SR1 is indicated by a texture.

The semiconductor device SD 1 includes a semiconductor substrate SUB, a semiconductor layer SL, an insulating film IF, a conductive film CF, and a wiring layer WL1. A portion of the semiconductor layer SL, the insulating film IF, and the conductive film CF constitute the first capacitive element C1. The wiring layer WL1 includes an interlayer insulating layer IIL, a via V, a first electrode pad PD1, a second electrode pad PD2, and a third electrode pad PD3.

The semiconductor substrate SUB supports the semiconductor layer SL. The semiconductor substrate SUB has a first conductivity type. The semiconductor substrate SUB is, for example, silicone substrate. The first conductivity type is p-type or n-type. Examples of the impurity contained in the p-type semiconductor substrate include boron (B) and indium (In). Examples of impurities contained in n-type semiconductor substrate include phosphorus (P), arsenic (As), and antimony (Sb). The semiconductor substrate SUB is electrically connected with the substrate terminal Tsub.

The semiconductor layer SL is formed on the semiconductor substrate SUB. The semiconductor layer SL includes a buried layer BL, a first semiconductor region SR1, second, a semiconductor region SR2, third, a semiconductor region SR3, a first buried insulating film BIF1, and a second buried insulating film BIF2. The semiconductor layer SL is, for example, a silicon layer containing a predetermined impurity in a predetermined region.

The buried layer BL is formed on an entirety or a portion of the first epitaxial layer EL1. From the viewpoint of electrically isolating the capacitive element C1 formed on the buried layer BL and the semiconductor substrate SUB from each other in the semiconductor layer SL, it is preferable that the semiconductor layer SL includes the buried layer BL. The buried layer BL is a semiconductor layer having a second conductivity type opposite to the first conductivity type. An impurity concentration of the buried layers BL is preferably 1×10¹⁸ cm⁻³ or more and 1×10²¹ cm⁻³ or less, for example.

The first semiconductor region SR1 is formed on the buried layer BL. When the buried layer BL is formed on an entirety of the semiconductor substrate SUB, the first semiconductor region SR1 is formed on the buried layer BL. When the buried layer BL is formed on a portion of the semiconductor substrate SUB, the first semiconductor region SR1 is formed on the buried layer BL and the semiconductor substrate SUB. The first semiconductor region SR1 has a first conductivity type. An impurity concentration of the first semiconductor region SR1, for example, it is preferably 1×10¹³ cm⁻³ or more and 1×10¹⁹ cm⁻³ or less, more preferably 1×10¹³ cm⁻³ or more and 1×10¹⁶ cm⁻³ or less. The first semiconductor region SR1 is electrically connected with the power supply terminal Tpw through the first electrode pad PD1.

The second semiconductor region SR2 form a portion of a main surface of the semiconductor layer SL. The second semiconductor region SR2 is exposed from the first buried insulating film BIF1 and the second buried insulating film BIF2. In first embodiment, the second semiconductor region SR2 is a lower electrode of the first capacitive element C1. A first resistive element R1 is formed by the second semiconductor region SR2. The second semiconductor region SR2 has the second conductivity type. An impurity concentration of the second semiconductor region SR2 is, for example, preferably 1×10¹⁸ cm⁻³ or more and 1×10¹⁹ cm⁻³ or less. The second semiconductor region SR2 is electrically connected with the output terminal Tout through the second electrode pad PD2.

The third semiconductor region SR3 is formed between the first semiconductor region SR1 and the second semiconductor region SR2. The third semiconductor region SR3 is directly contacted with the first semiconductor region SR1 and the second semiconductor region SR2. From the viewpoint of enhancing the current driving capability, it is preferable that the semiconductor device SD1 includes the third semiconductor region SR3. The third semiconductor region SR3 has the second conductivity type. An impurity concentration of the third semiconductor region SR3 is, for example, preferably 1×10¹⁶ cm⁻³ or more and 1×10¹⁷ cm⁻³ or less.

The second semiconductor region SR2, the first semiconductor region SR1, and the third semiconductor region SR3 form a diode element D (see FIG. 1). In first embodiment, the conductivity type of the second semiconductor region SR2 is p-type, and the conductivity type of the first semiconductor region SR1 and the conductivity type of the third semiconductor region SR3 are n-type.

The first buried insulating film BIF1 is formed on the main surface of the semiconductor layer SL. The first buried insulating film BIF1 is formed such that the first buried insulating film BIF1 surrounds the capacitive element C1 in plan view. As a result, the capacitive element C1 can be electrically insulated from a semiconductor element (not shown). The first buried insulating film BIF1 is an insulating film formed on the main surface of the semiconductor layer SL. The position, number, and size of the first buried insulating film BIF1 are not particularly limited as long as the capacitive element C1 can be electrically insulated from other semiconductor elements (not shown). The first buried insulating film BIF1 is formed of, for example, silicon oxide (SiO₂).

The second buried insulating film BIF2 penetrates the semiconductor layer SL such that the second buried insulating film BIF2 reaches the semiconductor substrate SUB. More specifically, the second buried insulating film BIF2 penetrates the first buried insulating film BIF1, the first semiconductor region SR1, and the buried layer BL. The second buried insulating film BIF2 is formed such that the second buried insulating film BIF2 surrounds the capacitive element C1 in plan view. As a result, the capacitive element C1 can be electrically insulated from a semiconductor element (not shown). The position, number, and size of the second buried insulating film BIF2 are not particularly limited as long as the capacitive element C1 can be electrically insulated from other semiconductor elements (not shown). A material of the second buried insulating film BIF2 is, for example, silicon oxide (SiO₂). From the viewpoint of further enhancing insulating characteristics, it is preferable that a void (an air gap) is formed within the second buried insulating film BIF2.

The insulating film IF is formed on the semiconductor layer SL. More specifically, the insulating film IF is formed on the second semiconductor region SR2. The insulating film IF is a dielectric film of the first capacitive element C1. A material of the insulating film IF is, for example, silicon oxide.

The conductive film CF is formed on the second semiconductor region SR2 through the insulating film IF. In plan view, a portion of the conductive film CF is formed on the first buried insulating film BIF1 without overlapping with the second semiconductor region SR2. From the viewpoint of ease of manufacturing, it is preferable that a portion of the conductive film CF does not overlap with the second buried insulating film BIF2 in plan view. In first embodiment, the conductive film CF is an upper electrode of the first capacitive element C1. The second resistive element R2 is formed of the conductive film CF. A material of the conductive film CF is, for example, polycrystal silicon having conductivity. The conductive film CF is electrically connected with the grounding terminal Tgnd through the third electrode pad PD3.

As described above, the first capacitive element C1 is constituted by the second semiconductor region SR2, the insulating film IF, and the conductive film CF. A thickness, a material, and the like of each element are appropriately adjusted in accordance with desired capacitance characteristics.

The wiring layer WL1 is formed on the semiconductor layer SL such that the wiring layer WL1 covers the first capacitive element C1 formed on the main surface of the semiconductor layer SL. The wiring layer WL1 may be formed of one wiring layer or more wiring layers. In the first embodiment, the wiring layer WL1 is formed of one wiring layer. The wiring layer is a layer including an interlayer insulating layer and one or both of a wiring and a via formed in the interlayer insulating layer. The via is, for example, a conductor member electrically connecting two wiring formed in layers that differ from each other.

The wiring layer WL1 includes an interlayer insulating layer IIL, a via V, a first electrode pad PD1, a second electrode pad PD2, and a third electrode pad PD3. Here, the electrode pad may be a wiring formed in an uppermost layer or a wiring formed in a lower layer than the uppermost layer in the wiring layer WL1.

The interlayer insulating layer IIL is formed on the semiconductor layer SL such that the interlayer insulating layer IIL covers the first capacitive element C1. A material of the first interlayer insulating layer IIL include, for example, silicon oxide. A thickness of the interlayer insulating layer IIL is not particularly limited.

The via V is formed in the interlayer insulating layer IIL such that the via V reaches the first semiconductor region SR1, the second semiconductor region SR2 or the conductive film CF. The first via V includes, for example, a barrier film and a conductive film formed on the barrier film. Examples of material for the barrier film include titanium (Ti), titanium nitride (TiN), tantalum (Ta), and tantalum nitride (TaN). Examples of material for the conductive film include tungsten (W) and aluminum (Al). The barrier film is not an indispensable element.

The first electrode pad PD1 is formed on the interlayer insulating layer IIL. The first electrode pad PD1 is electrically connected with the power supply terminal Tpw. Thus, the first electrode pad PD1 is configured to be electrically connected with the power supply circuit via the power supply terminal Tpw.

As the first electrode pad PD1, a well-known structure employed as an electrode pad in the semiconductor technology can be employed. The first electrode pad PD1 is, for example, a stacked film in which a barrier metal, a conductive film, and a barrier metal are stacked in this order. Examples of a material constituting the barrier metal include titanium (Ti), titanium nitride (TiN), tantalum (Ta), and tantalum nitride (TaN). Examples of a material of the conductive film include aluminum, copper, and tungsten.

The second electrode pad PD2 and the third electrode pad PD3 are the same as the first electrode pad PD1 except for the positions formed in the wiring layer WL. The second electrode pad PD2 is electrically connected with the output terminal Tout. Thus, the second electrode pad PD2 is configured to allow output signals to be output toward external circuits via the second electrode pad PD2 and the output terminal Tout. The third electrode pad PD3 is electrically connected with the grounding terminal Tgnd. Thus, the third electrode pad PD3 is configured to allow the grounding potential to be supplied through the grounding terminal Tgnd.

(Method of Manufacturing Semiconductor Device)

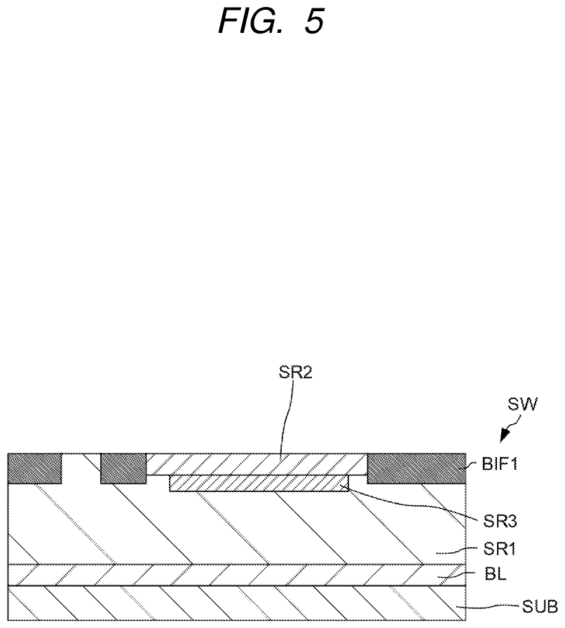

FIGS. 5 to 8 are a cross-sectional view showing exemplary steps included in a method of manufacturing the semiconductor device SD1 according to the first embodiment.

The method of manufacturing the semiconductor device SD according to the present embodiment includes (1) providing the semiconductor wafer SW, (2) forming the first capacitive element C1, (3) forming the second buried insulating film BIF₂, and (4) forming the multilayer wiring layer MWL1.

(1) Providing of Semiconductor Wafer SW

As shown in FIG. 5, a semiconductor wafer SW is provided. The semiconductor wafer SW includes the semiconductor substrate SUB and a part of the semiconductor layer SL formed on the semiconductor substrate SUB. In first embodiment, of the semiconductor layer SL, the semiconductor wafer SW including the buried layer BL, the first semiconductor region SR1, the second semiconductor region SR2, the third semiconductor region SR3 and the first buried insulating film BIF1, is provided.

The semiconductor substrate SUB may be purchased or manufactured, for example, as off-the-shelf products. The semiconductor substrate SUB is held on an electrostatic chuck.

The buried layer BL may be formed by implanting a predetermined impurity concentration into the surface of the semiconductor substrate SUB by ion implantation method, and then performing activation annealing. The buried layer BL may be formed by forming an epitaxial layer on the surface of the semiconductor substrate SUB by an epitaxial growth method, implanting an impurity into the epitaxial layer by an ion implantation method, and then performing activation annealing.

The first semiconductor region SR1 is formed on the buried layer BL by, for example, an epitaxial growth method, and then a predetermined impurity is introduced into the first semiconductor region SR1 by an ion implantation method. The second semiconductor region SR2 and the third semiconductor region SR3 may be formed by implanting an impurity into a predetermined region in the first semiconductor region SR1 by an ion implantation method, and then performing activation annealing.

The first buried insulating film BIF1 may be formed by forming a recess portion on the main surface of the first semiconductor region SR1 by an etching method, and then burying the recess portion with an insulating film. The first buried insulating film BIF1 may be formed by oxidizing a portion of the main surface of the first semiconductor region SR1 by a LOCOS method.

(2) Formation of First Capacitive Element C1

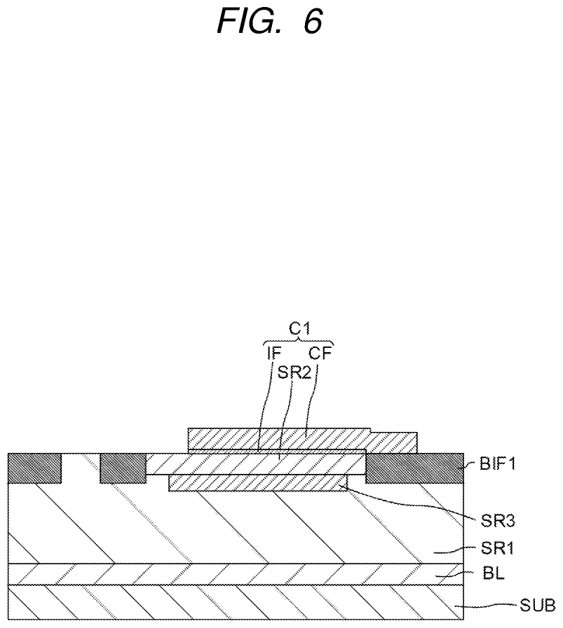

As shown in FIG. 6, the first capacitor C1 is formed on the main surface of the first semiconductor region SR1. In this step, the insulating film IF and the conductive film CF are formed, of the constituent elements of the first capacitive element C1.

First, the insulating film IF is formed on the main surface of the semiconductor layer SL. A method of forming the insulating film IF is, for example, a CVD method or a thermal oxidation method. The insulating film IF is formed on at least the second semiconductor region SR2.

Subsequently, the conductive film CF is formed on the insulating film IF. The conductive film CF is formed by, for example, forming a conductive layer by a CVD method or a sputtering method, and then patterning the conductive layer into a desired pattern.

(3) Forming Second Buried Insulating Film BIF2

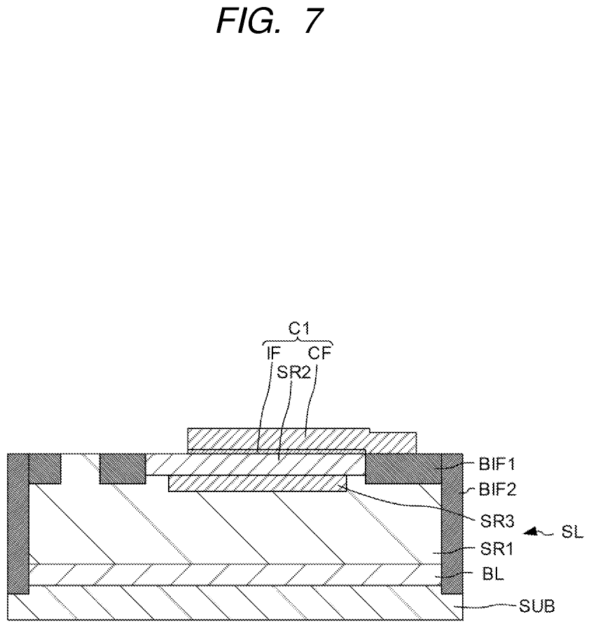

As shown in FIG. 7, the second buried insulating film BIF2 is formed in the semiconductor substrate SUB and the semiconductor layer SL. As a result, the semiconductor layer SL is formed. For example, after a trench penetrating the semiconductor layer SL is formed along the thickness direction of the semiconductor layer SL by an etching method so as to reach the semiconductor substrate SUB, an insulating film is formed so as to bury the trench, whereby the second buried insulating film BIF2 is formed. A method of forming the insulating film is, for example, a CVD method.

In the first embodiment, the second buried insulating film BIF2 is formed after the forming the first capacitive element C1, but the second buried insulating film BIF2 may be formed prior to the forming the first capacitive element C1. In other words, the second buried insulating film BIF2 may be formed in the providing the semiconductor wafer SW.

(4) Forming Wiring Layer WL1

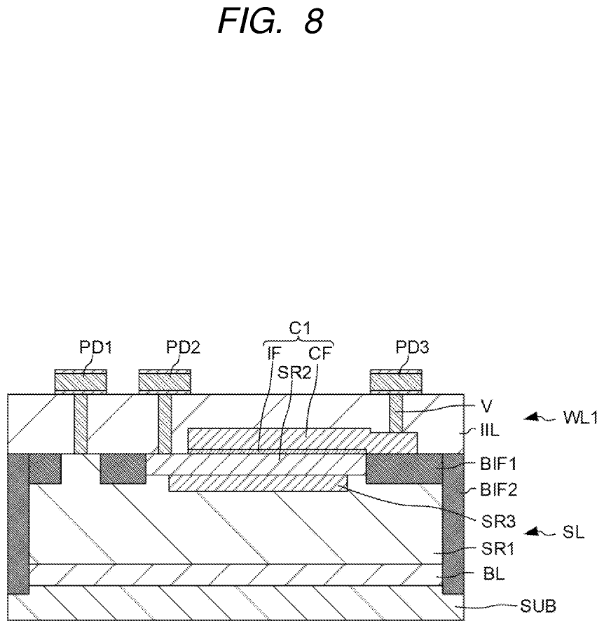

As shown in FIG. 8, the wiring layer WL1 is formed on the semiconductor layer SL so as to cover the capacitive element C1. In first embodiment, the interlayer insulating layer IIL, the via V, the first electrode pad PD1, the second electrode pad PD2, and the third electrode pad PD3 are formed.

The interlayer insulating layer IIL is formed by, for example, CVD method. A CMP treatment may be performed to an upper surface of the interlayer insulating layer IIL. The via V is formed by forming a through hole in the interlayer insulating layer IIL, and then burying the through hole with a conductive material. The first electrode pad PD1, the second electrode pad PD2 and the third electrode pad PD3 are formed by forming a conductive layer on the interlayer insulating layer IIL by a sputtering method, and then patterning the conductive layer into a desired pattern.

Subsequently, a structure obtained by the above steps is detached from the electrostatic chuck and diced to obtain a plurality of singulated semiconductor devices SD1. Finally, the semiconductor device SD1 is sealed with a sealing resin (sealing step).

The semiconductor device SD1 according to the present embodiment is manufactured by the above method of manufacturing. The method of manufacturing the semiconductor device SD1 according to the first embodiment may further include other steps as required. The other steps may be suitably employed from known method in the semiconductor art.

For example, the method of manufacturing the semiconductor device SD1 according to the first embodiment may include a connecting step. In the connecting step, the power supply terminal Tpw connected with the first electrode pad PD1 is electrically connected with the power supply circuit. The output terminal Tout connected with the second electrode pad PD2 is electrically connected with an external circuit. The grounding terminal Tgnd connected with the third electrode pad PD3 is electrically connected with the grounding line GND.

(Effect)

The semiconductor device SD1 according to the first embodiment includes the first electrode pad PD1 configured to be electrically connected with the first semiconductor region SR1 and configured to be electrically connected with the power supply circuit, the second electrode pad PD2 configured to be electrically connected with the second semiconductor region SR2 and configured to allow a signal to output toward the external circuit, and the third electrode pad PD3 configured to be electrically connected with the conductive film CF and configured to allow the grounding potential to be supplied. The low-pass filter circuit LPF is mainly constituted by the first capacitive element C1 including the second semiconductor region SR2, the insulating film IF, and the conductive film CF. The low-pass filter LPF according to the first embodiment does not include polycrystal silicon resistive element. Here, the polycrystal silicon resistive element occupies some area in the semiconductor device SD1. On the other hand, as described above, the low-pass filter LPF according to the first embodiment does not include polycrystal silicon resistive element. As a result, the semiconductor device SD1 according to the first embodiment can be miniaturized.

In semiconductor device SD1 according to the first embodiment, the diode element D formed of the first semiconductor region SR1 and the second semiconductor region SR2, and the first capacitive element C1 overlap with each other in plan view. As a result, the semiconductor device SD1 can be further miniaturized.

Further, the polycrystal silicon resistive element may deteriorate in characteristics due to stress generated in manufacturing process of the semiconductor device, for example, a sealing step. Specifically, in the polycrystal silicon resistive element, current flows along a direction along the main surface of the semiconductor layer SL. The stress in the sealing step is generated in a direction along the main surface of the semiconductor layer SL. Therefore, the electrical characteristics of the polycrystal silicon resistive element may deteriorate due to the stress. In contrast, in the low-pass filter circuit LPF according to the first embodiment, the resistive element corresponding to the polycrystal silicon resistive element is formed in the semiconductor layer SL. In the resistive element, current flows mainly along a direction perpendicular to the main surface of the semiconductor layer SL. Therefore, the electrical characteristic of the low-pass filter circuit LPF is less likely to be affected by the stress. That is, deterioration of the electrical characteristic of the low-pass filter circuit LPF due to the stress is suppressed. As a result, the characteristic of the semiconductor device SD1 can be improved.

### First Modification

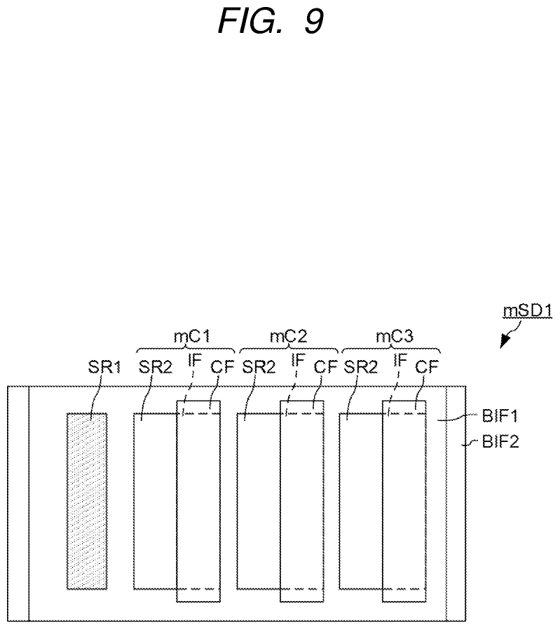

FIG. 9 is a plan view showing an exemplary configuration of a main portion of a semiconductor device mSD1 according to a first modification. In FIG. 9, a part of the configuration is omitted from the viewpoint of ease of viewing. In FIG. 9, the first semiconductor region SR1 is indicated by a texture.

As shown in FIG. 9, the semiconductor device mSD1 includes a plurality of capacitive elements spaced apart from each other. The semiconductor layer SL of the semiconductor device mSD1 include a plurality of second semiconductor regions SR2 spaced apart from each other, a plurality of insulating films IF spaced apart from each other, and a plurality of conductive films CF spaced apart from each other. The plurality of second semiconductor regions SR2, the plurality of insulating films IF, and the plurality of conductive films CF are formed so as to be adjacent to each other in the first direction along the main surface of the semiconductor layers SL. The semiconductor device mSD1 according to the first modification includes a capacitive element mC1, a capacitive element mC2, and a capacitive element mC3 which are formed adjacent to each other in the first direction. The plurality of second semiconductor regions SR2 may be integrally formed as a single member.

According to the first modification, the resistance (the resistance of the first resistive element R1) of the second semiconductor region SR2 corresponding to the lower electrode of the capacitive element mC1, mC2, mC3 can be further reduced.

### Second Modification

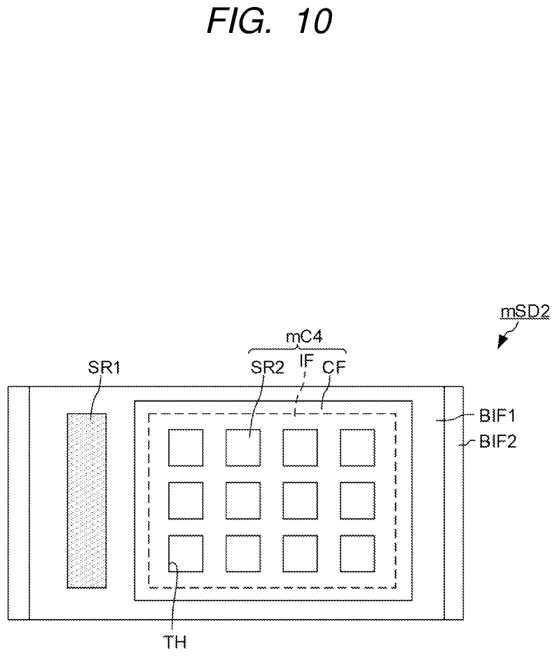

FIG. 10 is a plan view showing an exemplary configuration of a main portion of a semiconductor device mSD2 according to a second modification. In FIG. 10, a part of the configuration is omitted from the viewpoint of ease of viewing. In FIG. 10, the first semiconductor region SR1 is indicated by a texture.

As shown in FIG. 10, the semiconductor device mSD2 includes a capacitive element mC4. A through holes TH is formed in the insulating film IF and the conductive film mCF, each of the through holes TH exposes a portion of the second semiconductor region SR2. The number of the through hole TH is one or more. In second modification, the number of through holes TH is plural. A plurality of through holes TH are spaced apart from each other. Although not particularly illustrated, vias V are formed in each of the plurality of through holes TH. For example, the second electrode pad PD2 is electrically connected with the second semiconductor region SR2 through the via V formed in the through hole TH.

According to the second modification, the resistance (the resistance of the first resistor element R1) of the second semiconductor region SR2 corresponding to the lower electrode of the capacitive element mC4 can be further reduced.

### Third Modification

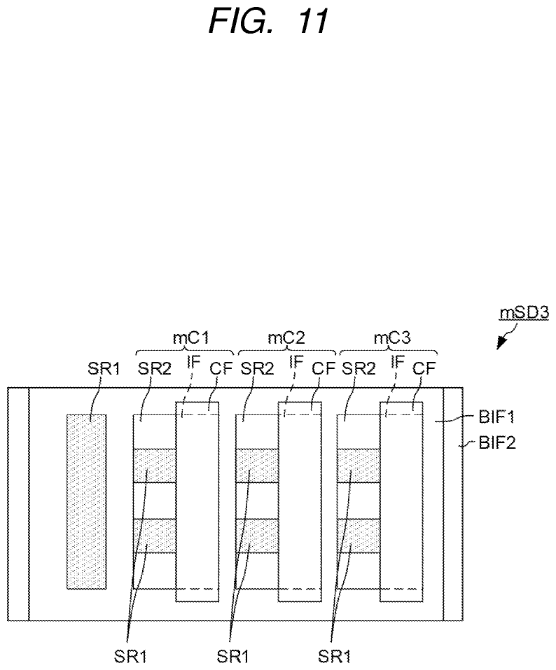

FIG. 11 is a plan view showing an exemplary configuration of a main portion of a semiconductor device mSD3 according to a third modification. In FIG. 11, a part of the configuration is omitted from the viewpoint of ease of viewing. In FIG. 11, the first semiconductor region SR1 is indicated by a texture.

As shown in FIG. 11, the semiconductor device mSD3 differs from the semiconductor device mSD1 according to the first modification in that a portion of the first semiconductor region SR1 is exposed from the second semiconductor region SR2. In third modification, in plan view, the portion of the first semiconductor region SR1 is sandwiched between a portion of the second semiconductor region SR2 and another portion of the second semiconductor region SR2 in the extending direction of the conductive film CF. In plan view, a plurality of first semiconductor regions SR1 may be integrally formed as a single member in a direction perpendicular to the extending direction. In plan view, the plurality of second semiconductor regions SR2 may be integrally formed in a direction perpendicular to the extending direction. The extending direction of the conductive film CF is a long side direction of the conductive film CF, and the direction perpendicular to the extending direction is a short side direction of the conductive film CF.

According to the third modification, the resistance (the resistance of the first resistive element R1) of the second semiconductor region SR2 corresponding to the lower electrode of the capacitive element mC1, mC2, mC3 can be further reduced. Further, according to the third modification, the driving capability of the diode element D can be improved.

### Second Embodiment

A semiconductor device according to the second embodiment includes a high-pass filter circuit.

Elements identical to those of the semiconductor device SD1 according to the first embodiment are denoted by the same reference numerals, and descriptions thereof are omitted.

(Circuit Configuration of Semiconductor Device)

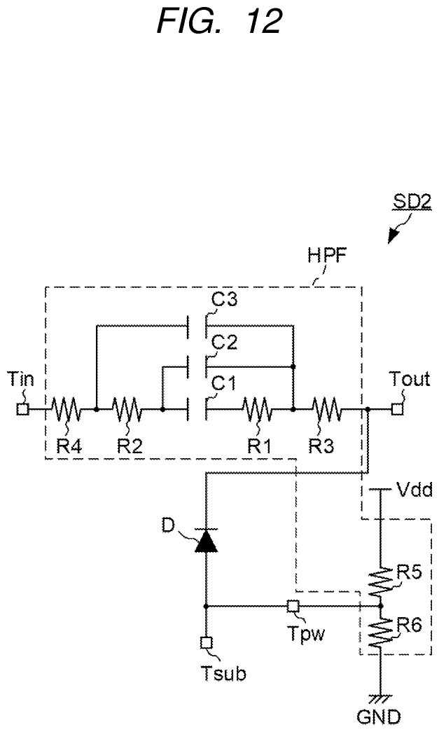

FIG. 12 is a circuit diagram showing an exemplary circuit configuration of a semiconductor device SD2 the according to a second embodiment.

As shown in FIG. 12, the semiconductor device SD2 includes a diode element D and a high-pass filter circuit HPF. The high-pass filter circuit HPF includes a first resistive element R1, a second resistive element R2, a third resistive element R3, a fourth resistive element R4, a fifth resistive element R5, a sixth resistive element R6, a first capacitive element C1, a second capacitive element C2, and a third capacitive element C3. The semiconductor device SD2 includes a substrate terminal Tsub, a power supply terminal Tpw, an input terminal Tin, and an output terminal Tout.

One end of the diode element D is coupled with the power supply terminal Tpw and the substrate terminal Tsub. Another end of the diode element D is coupled with the output terminal Tout and the high-pass filter circuit HPF. The diode element D is a pn junction diode element. The diode element D passes only a forward current supplied from the power supply terminal Tpw. When a reverse bias is applied to the diode element D, the diode element D functions as a capacitor.

The filter characteristic of the high-pass filter circuit HPF is mainly determined by the first capacitive element C1, the fifth resistive element R5, and the sixth resistive element R6. The first resistive element R1, the second resistive element R2, the third resistive element R3, the fourth resistive element R4, the second capacitive element C2, and the third capacitive element C3 may be used to adjust the filter characteristic of the high-pass filter circuit HPF.

The first resistive element R1, the second resistive element R2, the first capacitive element C1, the third resistive element R3, and the fourth resistive element R4 are coupled in series between the diode element D and the input terminal Tin. In the present embodiment, the first resistive element R1, the second resistive element R2, the first capacitive element C1, the third resistive element R3, and the fourth resistive element R4 are coupled in this order from the diode element D.

The fifth resistive element R5 is coupled between the power supply terminal Tpw and a power supply line Vdd. The sixth resistive element R6 is coupled between the power supply terminal Tpw and a grounding line GND. The fifth resistive element R5 and the sixth resistive element R6 are coupled in series between the power supply line Vdd and the grounding line GND.

One end of the second capacitive element C2 is coupled with a node between the first resistive element R1 and the third resistive element R3. Another end of the second capacitive element C2 is coupled with a node between the second resistive element R2 and the first capacitive element C1.

One end of the third capacitive element C3 is coupled with a node between the first resistive element R1 and the third resistive element R3. Another end of the third capacitive element C3 is coupled with a node between the second resistive element R2 and the fourth resistive element R4.

The input terminal Tin is configured to receive a signal from another circuit. The input terminal Tin is coupled with, for example, an electronic circuit (not shown).

The output terminal Tout is configured to output a signal toward another circuit. The output terminal Tout is coupled with, for example, an electronic circuit (not shown). The electronic circuit is not particularly limited, and is, for example, an operational amplifier circuit.

The input terminal Tin and the output terminal Tout may be internal terminals (electrode pads) formed in the semiconductor device SD1, or external terminals formed outside the semiconductor device SD1.

[Configuration of Semiconductor Device]

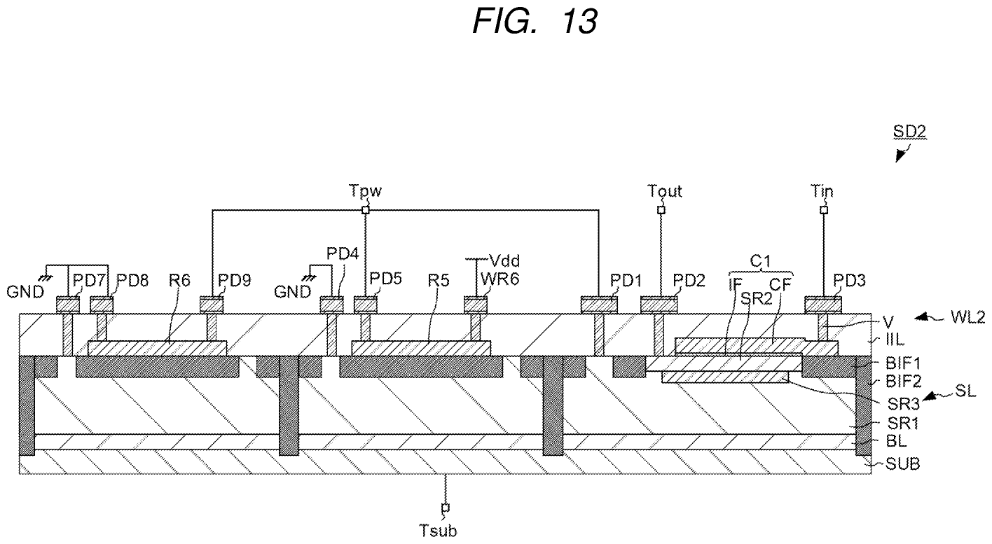

FIG. 13 is a diagram showing an exemplary configuration of the semiconductor device SD2 for realizing the above-described circuit configuration. FIG. 13 is a cross-sectional view showing an exemplary configuration of a main portion of a semiconductor device SD2 according to a second embodiment.

The semiconductor device SD2 includes a semiconductor substrate SUB, a semiconductor layer SL, an insulating film IF, a conductive film CF, a fifth resistive element R5, a sixth resistive element R6, and a wiring layer WL2. A portion of the semiconductor layer SL, the insulating film IF, and the conductive film CF constitute a capacitive element C1.

In the first semiconductor region SR1, a first region located directly below the first capacitive element C1 is electrically connected with the power supply terminal Tpw through the first electrode pad PD1. The first region overlaps with the first capacitive element C1 in plan view. In the first semiconductor region SR1, a second region located directly below the fifth resistive element R5 is electrically connected to the grounding line GND via the fourth electrode pad PD4. The second region overlaps with the fifth resistive element in plan view. In the first semiconductor region SR1, a third region located directly below the fifth resistive element R5 is electrically connected with the grounding line GND through the seventh electrode pad PD7. The third region overlaps with the fifth resistive element in plan view.

The second semiconductor region SR2 is electrically connected with the output terminal Tout through the second electrode pad PD2. The conductive film CF is electrically connected with the input terminal Tin through the third electrode pad PD3.

The fifth resistive element R5 is formed on the first buried insulating film BIF1. As a result, the fifth resistive element R5 can be electrically insulated from the first semiconductor region SR1. A material of the fifth resistive element R5 is, for example, polycrystal silicon having conductivity.

One end of the fifth resistive element R5 is electrically connected with the power supply terminal Tpw through the fifth electrode pad PD5. Another end of the fifth resistive element R5 is electrically connected with the power supply line Vdd via the sixth electrode pad PD6.

The sixth resistive element R6 is formed on the first buried insulating film BIF1. As a result, the sixth resistive element R6 can be electrically insulated from the first semiconductor region SR1. A material of the sixth resistive element R6 is, for example, polycrystal silicon having conductivity.

One end of the sixth resistive element R6 is electrically connected with the grounding line GND through the eighth electrode pad PD8. Another end of the sixth resistive element R6 is electrically connected with the power supply terminal Tpw through the ninth electrode pad PD9.

The fifth resistive element R5, the sixth resistive element R6, and the conductive film CF may be formed of the same material or different materials. It is preferable that the fifth resistive element R5, the sixth resistive element R6, and the conductive film CF are formed of the same material from the viewpoint that the respective elements can be formed in the one step. In the second embodiment, the fifth resistive element R5, the sixth resistive element R6, and the conductive film CF are formed of the same materials as each other.

The wiring layer WL2 includes an interlayer insulating layer IIL, a via V, a first electrode pad PD1, a second electrode pad PD2, a third electrode pad PD3, a fourth electrode pad PD4, a fifth electrode pad PD5, a sixth electrode pad PD6, a seventh electrode pad PD7, an eighth electrode pad PD8, and a ninth electrode pad PD9.

The interlayer insulating layer IIL is formed on the semiconductor layer SL such that the interlayer insulating layer IIL covers the first capacitive element C1, the fifth resistive element R5, and the sixth resistive element R6.

The first electrode pad PD1 is formed on the interlayer insulating layer IIL. The first electrode pad PD1 is electrically connected with the power supply terminal Tpw. Thus, the first electrode pad PD1 is configured to be electrically connected with the power supply circuit through the power supply terminal Tpw.

The second electrode pad PD2 to the ninth electrode pad PD9 are similar to the first electrode pad PD1 except for the formed in the wiring layer WL2.

The second electrode pad PD2 is electrically connected with the output terminal Tout. Thus, the second electrode pad PD2 is configured to allow a signal to be output toward an external circuit through the second electrode pad PD2 and the output terminal Tout.

The third pad PD3 are electrically connected with the input terminals T in. As a result, the third pad PD3 is configured to allow a signal to be input from the external circuit through the input terminal Tin.

The fourth electrode pad PD4, the seventh electrode pad PD7, and the eighth electrode pad PD8 are electrically connected with the grounding line GND. Thus, the fourth electrode pad PD4, the seventh electrode pad PD7, and the eighth electrode pad PD8 are configured to allow the grounding potential to be supplied.

The fifth electrode pad PD5 and the ninth electrode pad PD9 are electrically connected with the power supply terminal Tpw. Thus, the fifth electrode pad PD5 and the ninth electrode pad PD9 are configured to be electrically connected with the power supply circuits through the power supply terminal Tpw.

The sixth electrode pad PD6 is electrically connected with the power supply line Vdd. Thus, the sixth electrode pad PD6 is configured to allow the power supply potential to be supplied.

[Method of Manufacturing Semiconductor Device]

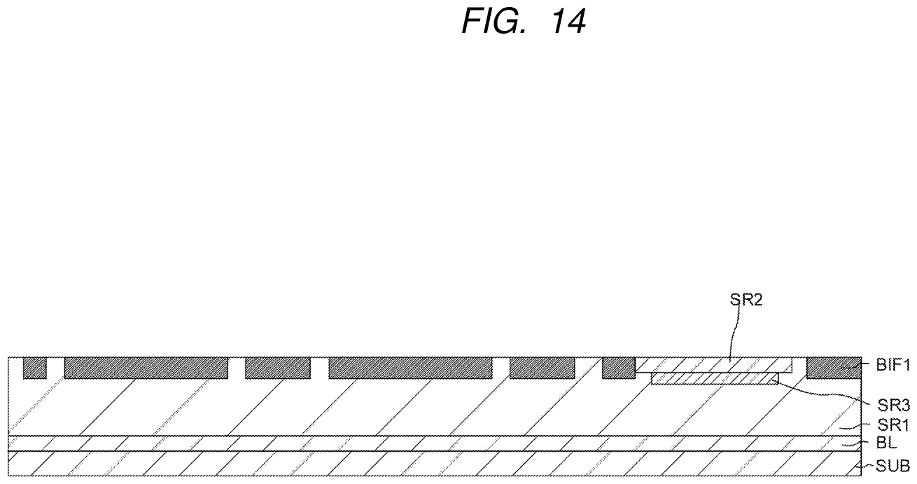

FIGS. 14 to 17 are a cross-sectional view showing exemplary steps included in the method of manufacturing the semiconductor device SD2 according to the second embodiment.

The method of manufacturing the semiconductor device SD2 includes (1) providing the semiconductor wafer SW, (2) forming the fifth resistive element R5, the sixth resistive element R6, and the capacitive element C1, (3) forming the second buried insulating film BIF2, and (4) forming the wiring layer WL2. The method of manufacturing the second embodiment according to semiconductor device SD2 differs from the method of manufacturing the semiconductor device SD1 according to the first embodiment in that the fifth resistive element R5 and the sixth resistive element R6 are formed in the step (2), and in that the via V and the wiring which are connected with the fifth resistive element R5 and the sixth resistive element R6 are further formed in the step (5).

(1) Providing of Semiconductor Wafer SW

As shown in FIG. 14, a semiconductor wafer SW is provided. Also, in the second embodiment, the semiconductor layer of the semiconductor wafer SW includes the buried layer BL, the first semiconductor region SR1, the second semiconductor region SR2, the third semiconductor region SR3 and the first buried insulating film BIF1.

(2) Formation of Fifth Resistive Element R5, Sixth Resistive Element R6, and First Capacitive Element C1

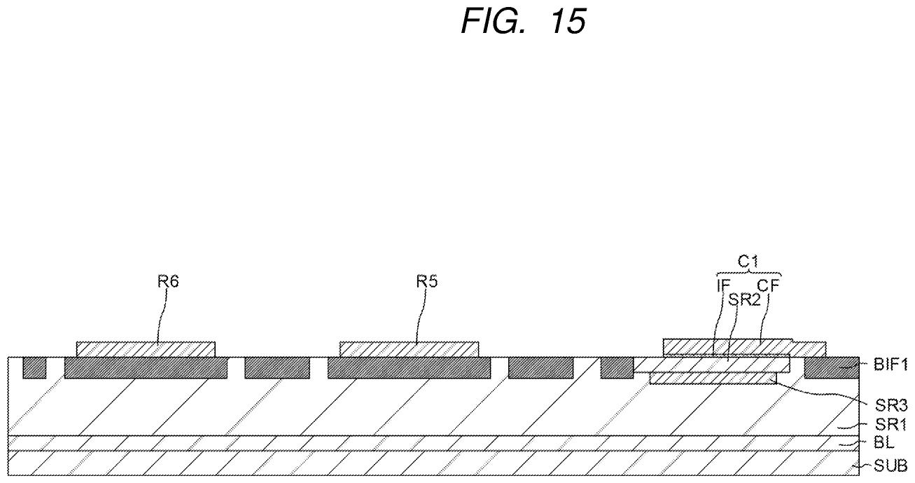

As shown in FIG. 15, the fifth resistive element R5, a sixth resistive element R6, and a first capacitive element C1 are formed on the main surface of the first semiconductor region SR1. In this step, the insulating film IF and the conductive film CF are formed of the constituent elements of the first capacitive element C1.

After an insulating film IF is formed on the main surface of the semiconductor layer SL, the conductive film CF is formed on the insulating film IF. The fifth resistive element R5 and the sixth resistive element R6 are formed on the first buried insulating film BIF1. The fifth resistive element R5, the sixth resistive element R6, and the conductive film CF are formed by forming a conductive layer by a CVD method or a sputtering method, and then patterning the conductive layer into a desired pattern. When the fifth resistive element R5, the sixth resistive element R6, and the conductive film CF are formed of the same material, the fifth resistive element R5, the sixth resistive element R6, and the conductive film CF can be formed in one step.

(3) Forming Second Buried Insulating Film BIF2

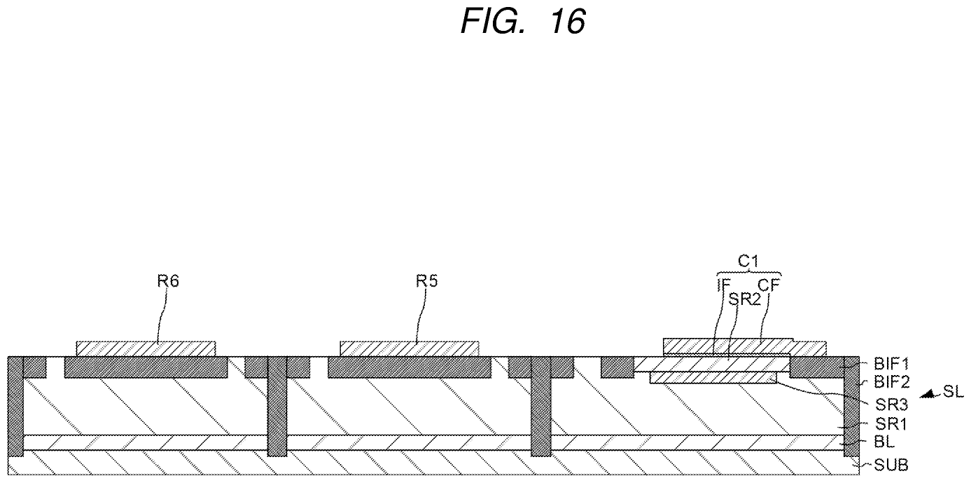

As shown in FIG. 16, the second buried insulating film BIF2 penetrating the semiconductor layer SL is formed so as to reach the semiconductor substrate SUB.

(4) Forming Wiring Layer WL2

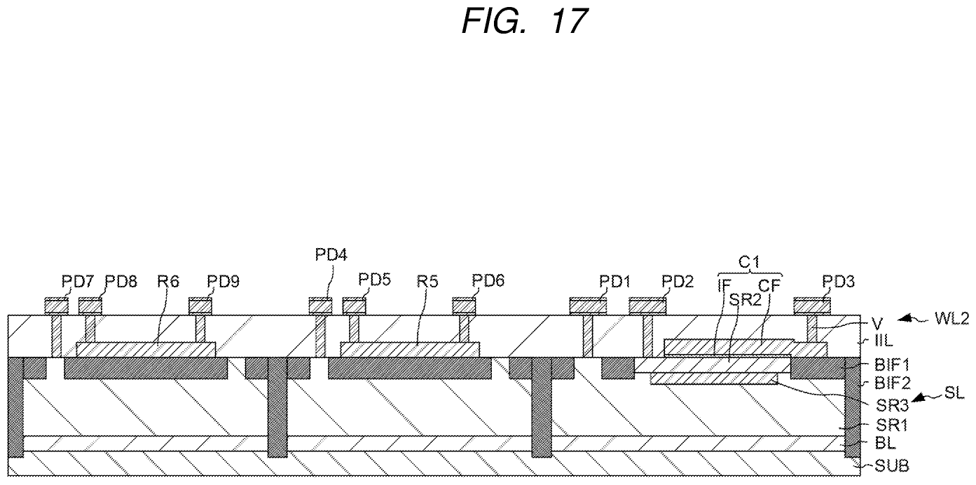

As shown in FIG. 17, the wiring layer WL2 is formed on the semiconductor layer SL so as to cover the fifth resistive element R5, the sixth resistive element R6, and the capacitive element C1. In the second embodiment, the interlayer insulating layer IIL, the via V, and the first electrode pad PD1 to the ninth electrode pad PD9 are formed.

Subsequently, the structure obtained by the above steps is detached from the electrostatic chuck and diced to obtain a plurality of semiconductor devices SD2 which are singulated. Finally, the semiconductor device SD2 is sealed with a sealing resin (sealing step).

The semiconductor device SD2 according to the present embodiment is manufactured by the above the method of manufacturing. The method of manufacturing the semiconductor device SD2 according to the second embodiment may further include other steps as required. The other steps may be suitably employed from known method in the semiconductor art.

For example, the method of manufacturing the semiconductor device SD2 according to the second embodiment may include a connecting step. In the connecting step, the power supply terminal Tpw connected with the first electrode pad PD1, the fifth electrode pad PD5, and the ninth electrode pad PD9 are electrically connected with the power supply circuit. The output terminal Tout connected with the second electrode pad PD2 is electrically connected with an external circuit. The input terminal Tin connected with the third electrode pad PD3 is electrically connected with the external circuit. The fourth electrode pad PD4, the seventh electrode pad PD7, or the eighth electrode pad PD8 is electrically connected with the grounding line GND. The sixth electrode pad PD6 is electrically connected with the power supply line Vdd.

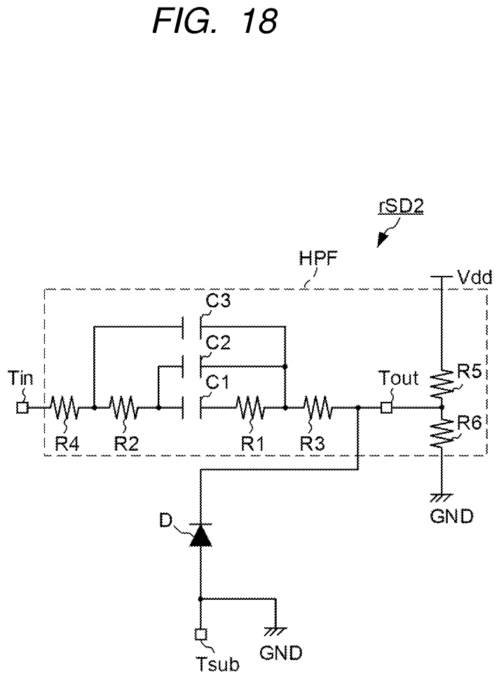

Here, main features of the semiconductor device SD2 will be described. For comparison, the comparative semiconductor device rSD2 will also be described. FIG. 18 is a circuit diagram showing an exemplary circuit configuration of the comparative semiconductor device rSD2.

As shown in FIG. 18, in the comparative semiconductor device rSD2, the fifth resistive element R5 is coupled between the output terminal Tout and the power supply line Vdd. The sixth resistive element R6 is coupled between the output terminal Tout and the grounding line GND. The fifth resistive element R5 and the sixth resistive element R6 are coupled in series between the power supply line Vdd and the grounding line GND.

Here, the impedance Z₁ determined based on a capacitance value C₁ of the first capacitive element C1 is expressed by the following equation (1). The impedance Z₂ determined based on the resistance value R₅ of the fifth resistive element R5 and the resistance value R₆ of the sixth resistive element R6 is expressed by the following equation (2). The impedance Z₃ determined based on the capacitance value Cₚ of the diode element D is expressed by the following equation (3).

Z₁=1/(2πfC₁) (1)

Z₂=R₅//R₆=R₅R₆/(R₅+R₆) (2)

Z₃=1/(2πfCₚ) (3)

[The f is a frequency of an input signal.]

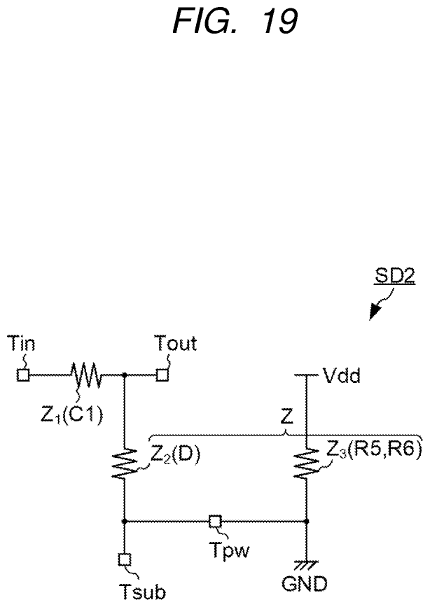

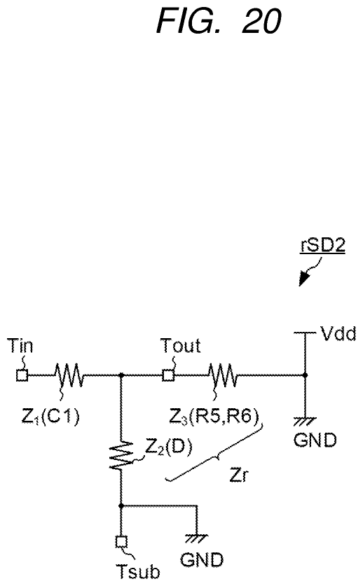

For convenience of explanation, the circuit configuration of the semiconductor device SD2 and the circuit configuration of the semiconductor device rSD2 are shown using only the impedance Z1, Z2 and Z3. FIG. 19 is a circuit diagram showing an exemplary circuit configuration of the second embodiment according to the semiconductor device SD2. FIG. 20 is a circuit diagram showing an exemplary circuit configuration of the comparative semiconductor device rSD2.

As shown in FIG. 19, in the semiconductor device SD2 according to the second embodiment, the impedance Z₁, the impedance Z₂, and the impedance Z₃ are coupled in series with each other. Therefore, the combined impedance Z of the impedance Z₂ and the impedance Z₃ is expressed by the following equation (4).

Z=Z₂+Z₃ (4)

Therefore, in the semiconductor device SD2 according to the second embodiment, a ratio V of the amplitude of the output signal output from the output terminal Tout to the amplitude of the input signal input from the input terminal Tin is expressed by the following equation (5).

V=Z/(Z₁+Z) (5)

On the other hand, as shown in FIG. 20, in the comparative semiconductor device rSD2, the impedance Z₂ and the impedance Z3 are coupled in parallel to the grounding line GND. Therefore, the combined impedance Zr of the impedance Z₂ and the impedance Z₃ is expressed by the following equation (6).

Zr=Z₂//Z₃=Z₂Z₃/(Z₂+Z₃) (6)

Therefore, in the comparative semiconductor device rSD2, a ratio Vr of the amplitude of the output signal output from the output terminal Tout to the amplitude of the input signal input from the input terminal Tin is expressed by the following equation (7).

Vr=Zr/(Z₁+Zr) (7)

Here, when the R₅ is 30 [kΩ], the R₆ is 30 [kΩ], the f is 1 [GHz], the C₁ is 1 [pF], and the Cₚ is 250 [fF], the Z₁, the Z₂, the Z₃, the Z, the Zr, the V, and the Vr are calculated, respectively.

Z₁=1/(2πfC₁)=160 [Ω] (1)

Z₂=R₅//R₆=R₅R₆/(R₅+R₆)=15000 [Ω] (2)

Z₃=1/(2πfCₚ)=637 [Ω] (3)

Z=Z₂+Z₃=15637 [Ω] (4)

V=Z/(Z₁+Z)=0.99 (5)

Zr=Z₂//Z₃=Z₂Z₃/(Z₂+Z₃)=611 [Ω] (6)

Vr=Zr/(Z₁+Zr)=0.79 (7)

As is clear from the results of the calculation of the above equations (5) and (7), it can be seen that the ratio of the amplitude of the output signal to the amplitude of the input signal is greater in the semiconductor device SD2 than that of the semiconductor device rSD2. This indicates that attenuation of the input signal is suppressed. The semiconductor device SD2 according to the second embodiment can transmit a signal with lower losses compared to semiconductor device rSD2.

Here, if the signal is to be transmitted at a decay ratio of the same level as that of the semiconductor device SD2 in the comparative semiconductor device rSD2 (that is, V˜Vr), for example, the impedance Z1 determined based on the capacitance value C1 of the first capacitive element C1 may be reduced. Considering the above equation (1), in order to increase the capacitance C1 of the first capacitive element C1, for example, the first capacitive element C1 needs to be increased in size. Therefore, in order to realize a decay ratio equivalent to that of the semiconductor device SD2 in the comparative semiconductor device rSD2, the semiconductor device rSD2 needs to be increased in size. On the other hand, in the semiconductor device SD2 according to the second embodiment, since the first capacitor C1 does not need to be made large, it is possible to realize miniaturization as compared with the comparative semiconductor device rSD2.

(Effect)

The semiconductor device SD2 according to the second embodiment includes the first electrode pad PD1 configured to be electrically connected with the first semiconductor region SR1 and configured to be electrically connected with a power supply circuit, the second electrode pad PD2 configured to be electrically connected with the second semiconductor region SR2 and configured to allow a signal to be output toward an external circuit, and the third electrode pad PD3 configured to be electrically connected with the conductive film CF and configured to receive an input signal from the external circuit. Therefore, as described above, the semiconductor device SD2 does not need to increase the size of the first capacitive element C1 in order to transmit signals with lower losses as compared with the comparative semiconductor device rSD2. As a result, according to the second embodiment, the semiconductor device SD2 can be miniaturized.

It should be noted that the present invention is not limited to the above-mentioned embodiments, and various modifications can be made without departing from the gist thereof. For example, in first and second embodiments, the semiconductor layer SL includes the second buried insulating film BIF2. However, the semiconductor layer SL may include a p-n junction formed by adjoining the p-type semiconductor region and the n-type semiconductor region instead of the second buried insulating film BIF2. As a result, the same function as that of the second buried insulating film BIF2 can be obtained.

In addition, even when a specific numerical value example is described, it may be a numerical value exceeding the specific numerical value, or may be a numerical value less than the specific numerical value, except when it is theoretically obviously limited to the numerical value. In addition, the component means “B containing A as a main component” or the like, and the mode containing other components is not excluded.

Further, at least a part of each embodiment and at least a part of each modification may be arbitrarily combined with each other.

What is claimed is:

1. A semiconductor device comprising:
a semiconductor substrate;
a semiconductor layer formed on the semiconductor substrate, the semiconductor layer comprising:
a first semiconductor region having a first conductivity type;
a second semiconductor region having a second conductivity type opposite to the first conductivity type;
an insulating film formed on the semiconductor layer;
a conductive film formed on the second semiconductor region through the insulating film;
a first electrode pad electrically connected with the first semiconductor region;
a second electrode pad electrically connected with the second semiconductor region; and
a third electrode pad electrically connected with the conductive film,
wherein the first electrode pad is configured to be electrically connected with a power supply circuit, and
wherein the second electrode pad is configured to allow a signal to be output toward an external circuit through the second electrode pad.

2. The semiconductor device according to claim 1,
wherein the third electrode pad is configured to allow a grounding potential to be supplied.

3. The semiconductor device according to claim 1, comprising a plurality of the insulating films spaced apart from each other,
wherein the plurality of insulating films are adjacent with each other in a first direction along a main surface of the semiconductor layer.

4. The semiconductor device according to claim 2,
wherein a through hole is formed in the insulating film and the conductive film,
wherein a via is formed in the through hole, and
wherein the second electrode pad is electrically connected with the second semiconductor region through the via.

5. The semiconductor device according to claim 2,
wherein a portion of the first semiconductor region is exposed from the second semiconductor region in plan view.

6. The semiconductor device according to claim 5,
wherein, in plan view, the portion of the first semiconductor region is sandwiched between a portion of the second semiconductor region and another portion of the second semiconductor region in an extending direction of the conductive film.

7. The semiconductor device according to claim 2,
wherein the semiconductor layer includes a third semiconductor region formed between the first semiconductor region and the second semiconductor region, and
wherein the third semiconductor region has the first conductivity type.

8. The semiconductor device according to claim 1,
wherein the third electrode pad is configured to receive a signal from an external circuit through the third electrode pad.

9. The semiconductor device according to claim 8, comprising a plurality of the insulating films spaced apart from each other,
wherein the plurality of insulating films are adjacent with each other in a first direction along a main surface of the semiconductor layer.

10. The semiconductor device according to claim 2,
wherein a through hole is formed in the insulating film and the conductive film,
wherein a via is formed in the through hole, and
wherein the second electrode pad is electrically connected with the second semiconductor region through the via.

11. The semiconductor device according to claim 8,
wherein a portion of the first semiconductor region is exposed from the second semiconductor region in plan view.

12. The semiconductor device according to claim 11,
wherein, in plan view, the portion of the first semiconductor region is sandwiched between a portion of the second semiconductor region and another portion of the second semiconductor region in an extending direction of the conductive film.

13. The semiconductor device according to claim 8,
wherein the semiconductor layer includes a third semiconductor region formed between the first semiconductor region and the second semiconductor region, and
wherein the third semiconductor region has the first conductivity type.
